(19) United States
(12) Patent Application Publication
(10) Pub. No.: US 2024/0170016 A1
(43) Pub. Date: May 23, 2024

(54) SPUTTERING DEVICE FOR MULTILAYER OPTICAL RECORDING MEDIUM AND METHOD FOR MANUFACTURING MULTILAYER OPTICAL RECORDING MEDIUM

(71) Applicant: SONY GROUP CORPORATION, TOKYO (JP)

(72) Inventors: MASATSUGU SUWABE, TOKYO (JP); TAKAHIRO IGARI, MIYAGI (JP); YOSHIO SHIRAI, MIYAGI (JP); TAKEHIRO SATO, TOKYO (JP)

(21) Appl. No.: 18/551,196

(22) PCT Filed: Mar. 4, 2022
(86) PCT No.: PCT/JP2022/009428

§ 371 Date: Sep. 19, 2023

(30) Foreign Application Priority Data
Mar. 31, 2021 (JP) 2021-062323

(51) Int. Cl. G11B 7/26; G11B 7/24038

(52) U.S. Cl. CPC G11B 7/266; G11B 7/24038

(57) ABSTRACT

Provided is a sputtering device for a multilayer optical recording medium capable of suppressing the occurrence of defects in a recording region. A sputtering device for a multilayer optical recording medium includes an outer mask, wherein the outer mask is configured to be capable of covering an outer periphery of a film-forming surface of an intermediate layer without coming into contact with the film-forming surface.

### TECHNICAL FIELD

The present disclosure relates to a sputtering device for a multilayer optical recording medium and a method for manufacturing the multilayer optical recording medium.

### BACKGROUND ART

Techniques for multilayering of information signal layers have been widely adopted in recent years to increase the storage capacities of optical recording media. Conventionally, sputtering devices for optical recording media are used with the same configuration for a single-layer optical recording medium and a multilayer optical recording medium. A proposed sputtering device for an optical recording medium includes an inner mask covering the inner periphery of the film-forming surface of a substrate during film formation and an outer mask covering the outer periphery of the film-forming surface of the substrate during film formation (for example, see PTL 1 and 2).

### CITATION LIST

### Patent Literature

### [PTL 1]

JP 2006-244537A

### [PTL 2]

JP 2006-351142A

### SUMMARY

### Technical Problem

However, the fabrication of a multilayer optical recording medium by using the sputtering device may cause a defect in a recording region.

An object of the present disclosure is to provide a sputtering device for a multilayer optical recording medium and a method for manufacturing the multilayer optical recording medium, which can suppress the occurrence of defects in a recording region.

### Solution to Problem

In order to solve the above-described problems, a first disclosure is a sputtering device for a multilayer optical recording medium, the sputtering device including an outer mask,
wherein the outer mask is configured to be capable of covering the outer periphery of the film-forming surface of an intermediate layer without coming into contact with the film-forming surface.

A second disclosure is a sputtering device for a multilayer optical recording medium, the sputtering device including an inner mask,
wherein the inner mask is configured to be capable of covering the inner periphery of a substrate or the film-forming surface of an intermediate layer and pressing a convex portion without coming into contact with the film-forming surface in a region outside the convex portion provided on the inner periphery of the substrate.

A third disclosure is a method for manufacturing a multilayer optical recording medium, the method including forming an inorganic layer on the film-forming surface of an intermediate layer by sputtering while covering the outer periphery of the film-forming surface with an outer mask such that the outer mask does not come into contact with the film-forming surface.

### BRIEF DESCRIPTION OF DRAWINGS

FIG. 1A is a cross-sectional view illustrating a part of a conventional sputtering device. FIG. 1B is an enlarged cross-sectional view of a region R1 in FIG. 1A.

FIG. 2A is a perspective view illustrating an example of an exterior of a multilayer optical recording medium. FIG. 2B is a schematic cross-sectional view illustrating an example of the configuration of the multilayer optical recording medium.

FIG. 3 is a plan view illustrating an example of the configuration of the multilayer optical recording medium.

FIG. 4 is a schematic diagram illustrating an example of the configuration of information signal layers.

FIG. 5 is a schematic diagram illustrating an example of the configuration of a sputtering device according to a first embodiment of the present disclosure.

FIG. 6A is a cross-sectional view illustrating an example of the configurations of an inner mask and an outer mask. FIG. 6B is an enlarged cross-sectional view illustrating a region R2 in FIG. 6A.

FIGS. 7A, 7B, 7C, 7D, and 7E are process diagrams for describing an example of a method for manufacturing the multilayer optical recording medium according to the first embodiment of the present disclosure.

FIGS. 8A, 8B, 8C, and 8D are process diagrams for describing an example of a method for manufacturing the multilayer optical recording medium according to the first embodiment of the present disclosure.

FIG. 9 is a cross-sectional view illustrating the inner mask provided for the conventional sputtering device.

FIG. 10 is a cross-sectional view illustrating an example of the configuration of a sputtering device according to a second embodiment of the present disclosure.

FIG. 11 is a cross-sectional view illustrating an example of the configuration of a sputtering device according to a modification example.

FIG. 12 is a graph showing a change of a reflectance with respect to the radius of the multilayer optical recording medium.

FIG. 13 is a plan view showing dent observation positions.

### DESCRIPTION OF EMBODIMENTS

Embodiments of the present disclosure will be described in the following order with reference to the drawings. In all the drawings of the following embodiments, the same or corresponding parts will be denoted by the same reference numerals.
1 First embodiment
1.1 Overview
1.2 Configuration of multilayer optical recording medium
1.3 Configuration of sputtering device
1.4 Method for manufacturing multilayer optical recording medium
1.5 Operation and effect
2 Second embodiment
2.1 Overview
2.2 Configuration of sputtering device
2.3 Method for manufacturing multilayer optical recording medium
2.4 Operation and effect
3 Modification examples
4 Examples

### 1 First Embodiment

### [1.1 Overview]

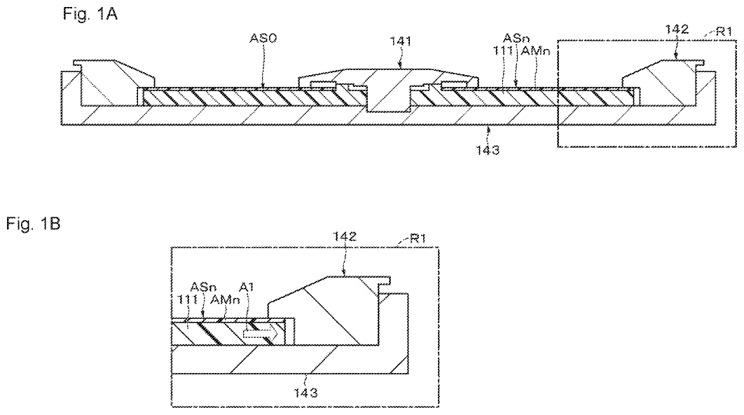

FIG. 1A is a cross-sectional view illustrating a part of a conventional sputtering device. FIG. 1B is a cross-sectional view illustrating an enlarged view of a region R1 of FIG. 1A. In the conventional sputtering device, a substrate 111 with an intermediate layer AMn formed thereon is disposed on a disc base 143, and an inorganic layer (e.g., a recording layer) is formed on a film-forming surface ASn of the intermediate layer AMn by sputtering while the outer periphery of the film-forming surface ASn of the intermediate layer AMn is covered with an outer mask 142.

According to the findings of the inventors, the fabrication of a multilayer optical recording medium by using the conventional sputtering device may cause a defect in a recording region as follows. When the inorganic layer is formed on the film-forming surface ASn of the intermediate layer AMn by sputtering using the conventional sputtering device, the substrate 111 thermally expands in the in-plane direction as indicated by an arrow A1 in FIG. 1B. Thus, the film-forming surface ASn of the intermediate layer AMn is scratched by the outer mask 142. The intermediate layer AMn is likely to peel off from the substrate 111, so that the outer periphery of the intermediate layer AMn curls up when the intermediate layer AMn is scratched by the outer mask 142. When ultraviolet curing resin is applied onto the intermediate layer AMn having such a curling portion (defect) and the relief pattern of a stamper is pressed onto the ultraviolet curing resin to transfer the uneven pattern, adhesion between the ultraviolet curing resin and the stamper decreases in the curling portion. Thus, the relief pattern of the stamper is insufficiently transferred over a wider range than the curling portion, causing a larger defect than the curling portion. Hence, even if the curling portion formed by the outer mask 142 has a small size, the curling portion finally forms a large defect.

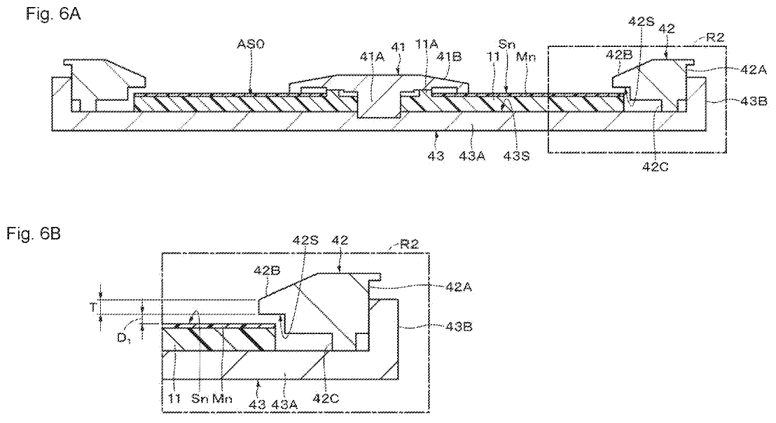

For this reason, the inventors eagerly examined the suppression of the defect. As a result, as illustrated in FIG. 6A, the inventors found a sputtering device including an outer mask 42 configured to cover the outer periphery of a film-forming surface Sn of an intermediate layer Mn without coming into contact with the film-forming surface Sn.

### [1.2 Configuration of Multilayer Optical Recording Medium]

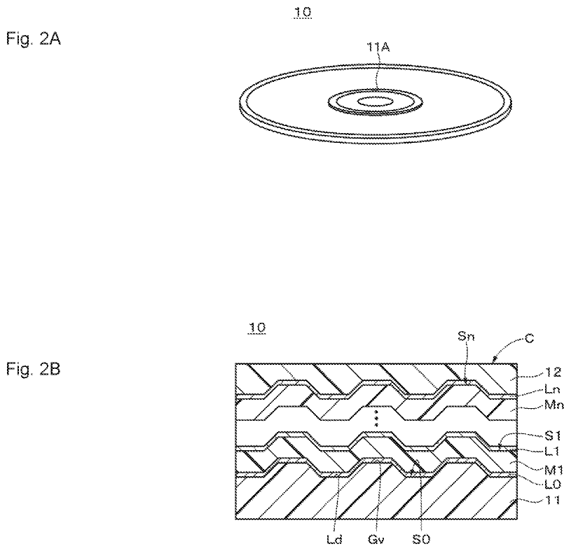

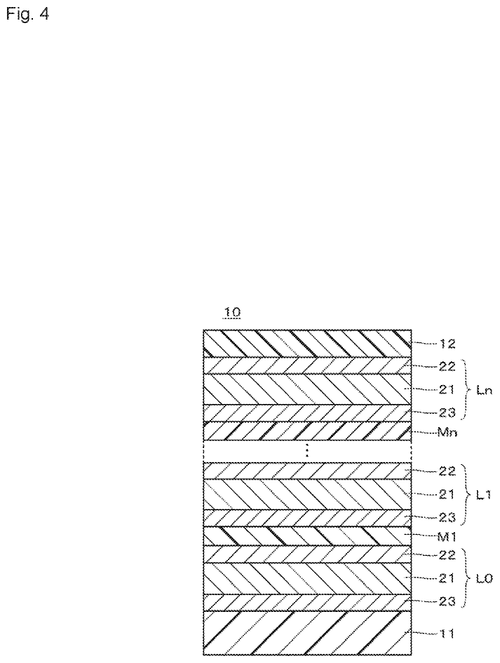

Referring to FIGS. 2A, 2B, 3, and 4, an example of the configuration of a multilayer optical recording medium 10 fabricated by a sputtering device according to a first embodiment of the present disclosure will be described below. As illustrated in FIG. 2A, the multilayer optical recording medium 10 has a disc shape with an opening (hereinafter will be referred to as “center hole”) at the center. The multilayer optical recording medium 10 is a so-called multilayer write-once optical recording medium. As illustrated in FIG. 2B, the multilayer optical recording medium 10 has a configuration in which an information signal layer L0, an intermediate layer M1, an information signal layer L1, . . . , the intermediate layer Mn, an information signal layer Ln, and a light transmitting layer 12, which is a cover layer, are stacked in this order on one main surface of a substrate 11. A surface near the light transmitting layer 12 serves as a light irradiation surface C that is irradiated with light for recording or reproducing an information signal in the information signal layers L0 to Ln. Note that n is, for example, an integer equal to or larger than 1, preferably an integer equal to or larger than 2, more preferably an integer equal to or larger than 3, and still more preferably an integer equal to or larger than 4. The information signal layer L0 is positioned on the innermost side with respect to the light irradiation surface C, and the information signal layers L1 to Ln are positioned thereabove. Therefore, the information signal layers L1 to Ln are configured to allow the transmission of a laser beam used for recording or reproduction.

In the multilayer optical recording medium 10 according to the first embodiment, the information signal is recorded or reproduced by emitting a laser beam to the information signal layers L0 to Ln from the light irradiation surface C near the light transmitting layer 12. For example, a laser beam having a wavelength from 400 nm to 410 nm is condensed by an objective lens having a numerical aperture of 0.84 to 0.86 and is emitted to the information signal layers L0 to Ln from the vicinity of the light transmitting layer 12, so that the information signal is recorded or reproduced. The information signal layers L0 to Ln have a storage capacity of, for example, 25 GB or more with respect to a wavelength of 405 nm and a numerical aperture NA of 0.85 of a condenser lens. The multilayer optical recording medium 10 configured thus is, for example, a multilayer Blu-ray Disc (BD (registered trademark)).

The substrate 11, the information signal layers L0 to Ln, the intermediate layers M1 to Mn, and the light transmitting layer 12 that constitute the multilayer optical recording medium 10 will be sequentially described below.

### Substrate

For example, the substrate 11 has a disc shape with a center hole at the center. The substrate 11 has a convex portion 11A on the inner periphery of a film-forming surface S0. The film-forming surface S0 of the substrate 11 is, for example, an uneven surface, and the information signal layer L0 is formed on the uneven surface. Hereinafter, in the uneven surface, a concave portion will be referred to as a land Ld, and a convex portion will be referred to as a groove Gv.

For example, the land Ld and the groove Gv are formed in various shapes such as a spiral and a concentric circle. Moreover, for example, wobbles (meanders) are made on the land Ld and/or the groove Gv to stabilize a linear velocity or add address information.

The diameter of the substrate 11 is selected to be, for example, 120 mm. The thickness of the substrate 11 is selected in consideration of rigidity and is preferably 0.3 mm to 1.3 mm, is more preferably 0.6 mm to 1.3 mm, and is selected to be, for example, 1.1 mm. The diameter of the center hole is selected to be, for example, 15 mm.

As the material of the substrate 11, for example, a plastic material or glass can be used. In consideration of the cost, a plastic material is preferably used. As the plastic material, for example, a polycarbonate resin, a polyolefin resin, or an acrylic resin can be used.

### Information Signal Layer

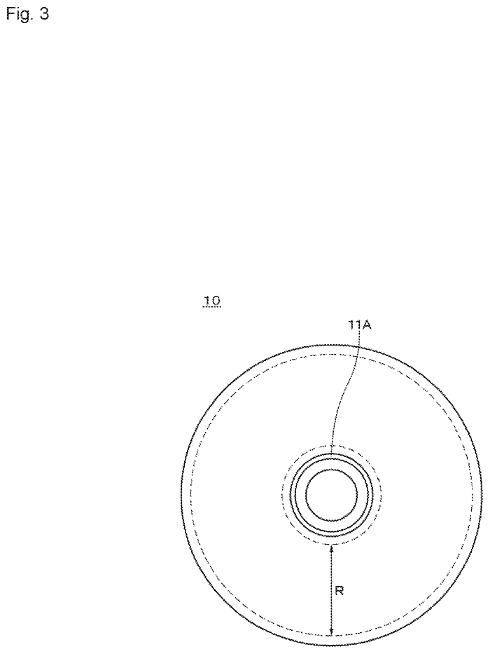

As illustrated in FIG. 3, a film-forming area R of the information signal layers L0 to Ln is set at a position inside the outer periphery of the film-forming surface S0 of the substrate 11 and outside the center hole. This configuration is set to cover the edges of the information signal layers L0 to Ln with the intermediate layers M1 to Mn and the light transmitting layer 12 so as to improve the corrosion proof of the information signal layers L0 to Ln. The film-forming area R is set in a range of, for example, 38 mm to 119 mm in diameter.

As illustrated in FIG. 2, the information signal layers L0 to Ln each include, for example, a recording layer 21 having an upper surface (first main surface) and a lower surface (second main surface), a dielectric layer 22 provided next to the upper surface of the recording layer 21, and a dielectric layer 23 provided next to the lower surface of the recording layer 21. With this configuration, the storage reliability of the information signal layers L0 to Ln can be improved. In this configuration, among the main surfaces of the recording layer 21, the upper surface is the main surface irradiated with a laser beam for recording or reproducing the information signal and the lower surface means the main surface opposite to the main surface irradiated with the laser beam, that is, the main surface near the substrate. The recording layer 21, the dielectric layer 22, and the dielectric layer 23 are examples of an inorganic layer.

### Recording Layer

The recording layer 21 is configured such that the information signal can be recorded by the irradiation of a laser beam. Specifically, the recording layer 21 is configured such that a recording mark can be formed by the irradiation of a laser beam. The recording layer 21 is an inorganic recording layer containing, as a principal component, a metallic oxide serving as an inorganic recording material. The metallic oxide is, for example, an inorganic recording material (MnO material) containing manganese oxide, an inorganic recording material (PdO material) containing palladium oxide, an inorganic recording material (CuO material) containing copper oxide, or an inorganic recording material (AgO material) containing silver oxide.

The thickness of the recording layer 21 is preferably in a range of 25 nm to 60 nm and is more preferably in a range of 30 nm to 50 nm.

### Dielectric Layer

The dielectric layers 22 and 23 have a function as an oxygen barrier layer. This can improve the durability of the recording layer 21. In addition, the dielectric layers 22 and 23 may have the function of suppressing the escape of oxygen in the recording layer 21. This can suppress a change in the film quality of the recording layer 21 and secure preferable film quality as the recording layer 21. In addition, the dielectric layers 22 and 23 may also have the function of improving the recording characteristics.

The dielectric layers 22 and 23 include dielectrics. The dielectric contains, for example, at least one selected from the group consisting of oxides, nitrides, sulfides, carbides and fluorides. As a material of the dielectric layers 22 and 23, the same material or different materials can be used. Examples of oxides include oxides of at least one element selected from the group consisting of In, Zn, Sn, Al, Si, Ge, Ti, Ga, Ta, Nb, Hf, Zr, Cr, Bi and Mg. Examples of nitrides include nitrides of at least one element selected from the group consisting of In, Sn, Ge, Cr, Si, Al, Nb, Mo, Ti, Nb, Mo, Ti, W, Ta and Zn, and preferably include nitrides of at least one element selected from the group consisting of Si, Ge and Ti. Examples of sulfides include Zn sulfides. Examples of carbides include carbides of at least one element selected from the group consisting of In, Sn, Ge, Cr, Si, Al, Ti, Zr, Ta and W, and preferably include carbides of at least one element selected from the group consisting of Si, Ti and W. Examples of fluorides include fluorides of at least one element selected from the group consisting of Si, Al, Mg, Ca and La. Specific examples of these mixtures include ZnS-SiO₂, SiO₂-In₂O₃-ZrO₂(SIZ), SiO₂-Cr₂O₃-ZrO₂(SCZ), In₂O₃-SnO₂(ITO), In₂O₃-CeO₂(ICO), In₂O₃-Ga₂O₃(IGO), In₂O₃-Ga₂O₃-ZnO(IGZO), Sn₂O₃-Ta₂O₅(TTO), TiO₂-SiO₂, AL₂O₃-ZnO, and Al₂O₃-BaO.

The thickness of the dielectric layer 23 is preferably in a range of 2 nm to 30 nm. The thickness of the dielectric layer 22 is preferably in a range of 2 nm to 50 nm.

### Intermediate Layer

The intermediate layers M1 to Mn act to separate the information signal layers L0 to Ln with a physically and optically sufficient distance and have uneven surfaces. On the uneven surface, for example, the concentric or spiral land Ld and the groove Gv are formed. The thicknesses of the intermediate layers M1 to Mn are preferably set at 9 μm to 50 μm. The material of the intermediate layers M1 to Mn is not particularly limited. A UV curable acrylic resin is preferably used. The intermediate layers M1 to Mn serve as optical paths for a laser beam for recording and reproducing the information signal in the inner layer and thus preferably have sufficiently high light transmission.

### Light Transmitting Layer

The light transmitting layer 12 is, for example, a resin layer obtained by curing photosensitive resin, e.g., ultraviolet curing resin. The material of the resin layer is, for example, ultraviolet curing acrylic resin. Alternatively, the light transmitting layer 12 may be configured with a light transmitting sheet having an annular shape and an adhesive layer for bonding the light transmitting sheet onto the substrate 11. The light transmitting sheet is preferably made of a material having low absorptive power relative to a laser beam used for recording and reproduction. Specifically, the light transmitting sheet is preferably made of a material having a transmittance of 90% or higher. As the material of the light transmitting sheet, for example, a polycarbonate resin material or polyolefin resin (e.g., Zeonex (registered trademark)) can be used. As the material of the adhesive layer, for example, ultraviolet curing resin or a pressure sensitive adhesive (PSA: Pressure Sensitive Adhesive) can be used.

The thickness of the light transmitting layer 12 is preferably selected from the range of 10 μm to 177 μm. The thickness is selected to be, for example, 100 μm. The thin light transmitting layer 12 is combined with, for example, an objective lens having a high NA (numerical aperture) of about 0.85, achieving high-density recording.

### [1.3 Configuration of Sputtering Device]

The sputtering device for forming the recording layer 21 on the film-forming surface Sn of the intermediate layer Mn, the sputtering device for forming the dielectric layer 22 on the film-forming surface Sn of the intermediate layer Mn, and the sputtering device for forming the dielectric layer 23 on the film-forming surface Sn of the intermediate layer Mn have the same configuration. Thus, the sputtering device for forming the recording layer 21 on the film-forming surface Sn of the intermediate layer Mn will be described below.

Moreover, the sputtering device for forming the recording layer 21 on the film-forming surface S0 of the substrate 11, the sputtering device for forming the dielectric layer 22 on the film-forming surface S0 of the substrate 11, and the sputtering device for forming the dielectric layer 23 on the film-forming surface S0 of the substrate 11 may have the same configuration as the sputtering device for forming the recording layer 21 on the film-forming surface Sn of the intermediate layer Mn.

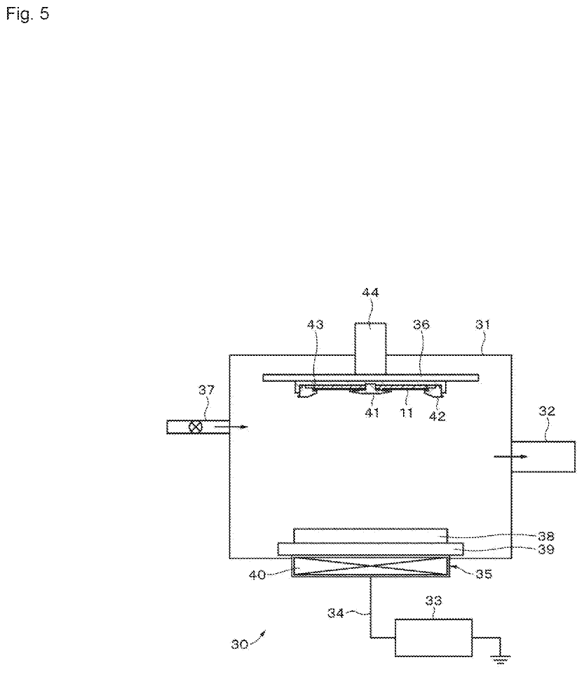

Referring to FIG. 5, an example of the configuration of a sputtering device 30 according to the first embodiment of the present disclosure will be described below. The sputtering device 30 is used for forming the recording layer 21 on the film-forming surface Sn of the intermediate layer Mn.

The sputtering device 30 is a sputtering device for a multilayer optical recording medium. The sputtering device 30 includes a vacuum chamber 31 serving as a film-forming chamber, a vacuum control unit 32 that controls a vacuum in the vacuum chamber 31, a plasma-discharge DC high voltage power supply 33, a sputtering cathode part 35 connected to the plasma-discharge DC high-voltage power supply 33 via a power supply line 34, a palette 36 opposed to the sputtering cathode part 35 at a predetermined distance, and a sputtering gas supply unit 37 that supplies sputtering gas, for example, inert gas of Ar or the like or reactant gas into the vacuum chamber 31.

The sputtering cathode part 35 includes a target 38 acting as a negative electrode, a backing plate 39 configured to fix the target 38, and a magnet system 40 provided on the opposite side of the backing plate 39 from the side where the target 38 is fixed.

The palette 36 acting as a positive electrode and the target 38 acting as a negative electrode constitute a pair of electrodes. On the palette 36, the substrate 11 serving as a film-formed body is opposed to the sputtering cathode part 35 with a disk base 43 interposed between the palette 36 and the substrate 11. On the disk base 43, an inner mask 41 and an outer mask 42 are provided. The inner periphery of the film-forming surface S0 of the substrate 11 attached onto the palette 36 is covered with the inner mask 41, and the outer periphery is covered with the outer mask 42. On the opposite side of the palette 36 from the side where the disk base 43 is attached, a substrate rotation driving unit 44 for rotating the palette 36 is provided.

Referring to FIGS. 6A and 6B, an example of the configurations of the disk base 43, the inner mask 41, and the outer mask 42 will be described below.

On the disk base 43, the substrate 11 is disposed with the intermediate layer Mn formed thereon. The disk base 43 includes a plate 43A and a wall portion 43B. The plate 43A has a placement surface 43S opposed to the backing plate 39, and the substrate 11 with the intermediate layer Mn formed thereon is disposed on the placement surface 43S. The plate 43A is attached on the palette 36. The plate 43A is circular in plan view from the direction of the backing plate 39.

The wall portion 43B is provided on the outer periphery of the placement surface 43S of the plate 43A. The wall portion 43B is ring-shaped in plan view from the direction of the backing plate 39. The outer mask 42 is fit inside the wall portion 43B.

The inner mask 41 is configured to be capable of fixing the substrate 11 to the disk base 43 by pressing the inner periphery of the substrate 11. Moreover, the inner mask 41 is configured to be capable of covering the inner periphery of the film-forming surface Sn of the intermediate layer Mn. The inner mask 41 covering the inner periphery of the film-forming surface Sn of the intermediate layer Mn allows the film-forming area R of the recording layer 21 to be set at a position separated from the inner periphery of the film-forming surface Sn of the intermediate layer Mn (see FIG. 3). Thus, the inner periphery of the recording layer 21 can be covered with the intermediate layer Mn and the light transmitting layer 12, thereby improving the corrosion proof of the multilayer optical recording medium 10. The inner mask 41 may be a known mask.

The inner mask 41 is provided at the central portion of the placement surface 43S. The inner mask 41 is circular in plan view from the direction of the backing plate 39. The inner mask 41 includes a base portion 41A and a protruding portion 41B. The base portion 41A is fit into the center hole of the substrate 11. The base portion 41A is shaped like a cylinder having substantially the same diameter as the center hole. The protruding portion 41B covers the inner periphery of the film-forming surface Sn of the intermediate layer Mn. The protruding portion 41B evenly protrudes from the peripheral face of the base portion 41A toward the outer mask 42.

The outer mask 42 is configured to be capable of covering the outer periphery of the film-forming surface Sn of the intermediate layer Mn without coming into contact with the film-forming surface Sn. The outer mask 42 covering the outer periphery of the film-forming surface Sn allows the setting of the film-forming area R of the recording layer 21 at a position separated from the outer periphery of the film-forming surface Sn of the intermediate layer Mn (see FIG. 3). Thus, the outer periphery of the recording layer 21 can be covered with the intermediate layer Mn and the light transmitting layer 12, thereby improving the corrosion proof of the multilayer optical recording medium 10. Since the outer mask 42 does not come into contact with the film-forming surface Sn of the intermediate layer Mn, scratches on the film-forming surface Sn of the intermediate layer Mn by the outer mask 42 can be suppressed when the substrate 11 thermally expands during the formation of the recording layer 21. This can suppress the curling of the outer periphery of the intermediate layer Mn. Thus, the occurrence of defects caused by the curling can be suppressed. The outer mask 42 is provided on the outer periphery of the placement surface 43S. The outer mask 42 is ring-shaped in plan view from the direction of the backing plate 39. The outer mask 42 includes a base portion 42A, a protruding portion 42B, and one or more convex portions 42C.

The base portion 42A is fit inside the wall portion 43B. The protruding portion 42B covers the outer periphery of the film-forming surface Sn of the intermediate layer Mn while being separated from the film-forming surface Sn. The protruding portion 42B evenly protrudes from the inner periphery of the base portion 42A toward the inner mask 41. The protruding portion 42B has a facing surface 42S that faces the placement surface 43S, that is, the film-forming surface Sn of the intermediate layer Mn. The facing surface 42S is a flat surface parallel to the placement surface 43S. On the upper surface of the protruding portion 42B, that is, on the opposite side from the facing surface 42S, an inclined face is formed from the upper surface of the base portion 42A. The inclined face decreases in height from the outer periphery toward the inner periphery of the placement surface 43S.

The convex portion 42C is provided at the bottom of the base portion 42A. The convex portion 42C holds the base portion 42A above the placement surface 43S. With this configuration, the protruding portion 42B is held above the film-forming surface Sn of the intermediate layer Mn. A distance between the protruding portion 42B and the film-forming surface Sn of the intermediate layer Mn is set by the height of the convex portion 42C. The convex portion 42C is shaped like an arch or a circle.

The outer mask 42 is configured to be capable of setting a distance D₁ between the facing surface 42S of the protruding portion 42B and the film-forming surface Sn of the intermediate layer Mn (hereinafter will be referred to as “flying height D₁ of the outer mask 42” as appropriate) preferably in a range of 50 μm to 400 μm and more preferably in a range of 150 μm to 400 μm. When the flying height D₁ of the outer mask 42 is 50 μm or more, the occurrence of defects on the multilayer optical recording medium 10 can be suppressed. When the flying height D₁ of the outer mask 42 is 400 μm or less, a change of a reflectance on the outer periphery of the multilayer optical recording medium 10 can be suppressed.

### [1.4 Method for Manufacturing Multilayer Optical Recording Medium]

Referring to FIGS. 5, 6, 7A to 7E, and 8A to 8D, an example of a method for manufacturing the multilayer optical recording medium according to the first embodiment of the present disclosure will be described below.

### Steps of Molding Substrate 11

First, the substrate 11 is molded with an uneven surface formed on one main surface. As a method of molding the substrate 11, for example, an injection molding (injection) method or a photopolymerization method (2P method: Photo Polymerization) can be used.

### Steps of Forming Information Signal Layer L0

The information signal layer L0 is then formed by sequentially stacking the dielectric layer 23, the recording layer 21, and the dielectric layer 22 on the substrate 11 by, for example, sputtering. At this point, the sputtering device in FIG. 5 may be used.

### Steps of Forming Intermediate Layer M1

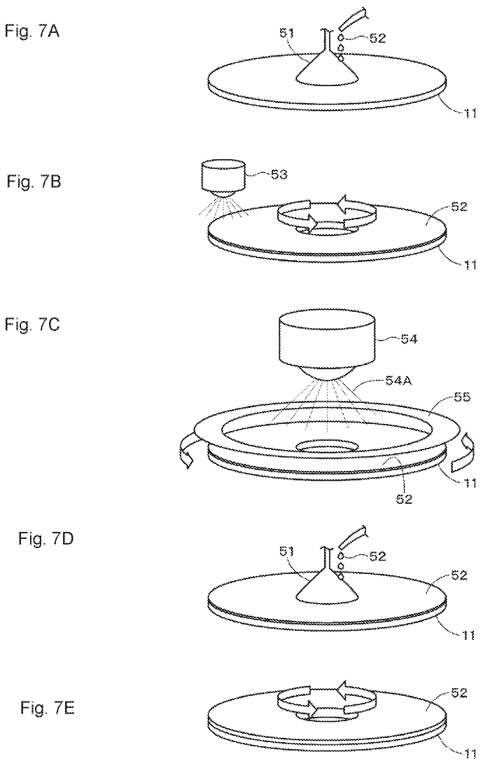

The substrate 11 is then placed on the spin tray (not illustrated) of a spin coating device. Subsequently, as illustrated in FIG. 7A, a center cap 51 is fit to the center hole of the substrate 11, and then ultraviolet curing resin 52 is applied onto the center cap 51. Thereafter, as illustrated in FIG. 7B, the spin tray is rotated while the outer periphery of the film-forming surface S0 of the substrate 11 is irradiated with infrared rays 53A by an infrared irradiation device 53. The ultraviolet curing resin 52 is spread from the inner periphery to the outer periphery of the substrate 11 by a centrifugal force and is applied to the film-forming surface S0 of the substrate 11.

As illustrated in FIG. 7C, the film-forming surface S0 of the substrate 11 is irradiated with ultraviolet rays 54A by an ultraviolet irradiation device 54 while the outer periphery of the film-forming surface S0 of the substrate 11 is covered with an outer mask 55, so that the ultraviolet curing resin 52 applied to the film-forming surface S0 of the substrate 11 is semi-cured. The spin tray is then rotated. This removes the protrusion of the ultraviolet curing resin 52 on the outer periphery of the film-forming surface S0 of the substrate 11.

Subsequently, as illustrated in FIG. 7D, the center cap 51 is fit to the center hole of the substrate 11, and then the ultraviolet curing resin 52 is applied onto the center cap 51. The spin tray is then rotated as illustrated in FIG. 7E. The ultraviolet curing resin 52 is spread from the inner periphery to the outer periphery of the substrate 11 by a centrifugal force and is applied to the film-forming surface S0 of the substrate 11.

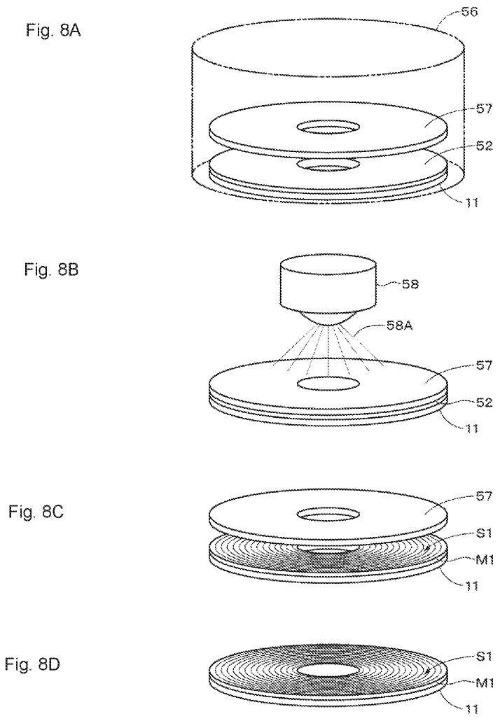

Thereafter, as illustrated in FIG. 8A, the substrate 11 is conveyed into a vacuum chamber 56, and then in a vacuum, the relief pattern of a soft stamper 57 is pressed to the ultraviolet curing resin 52 evenly applied on the film-forming surface S0 of the substrate 11. Subsequently, in a state in which the soft stamper 57 is pressed to the ultraviolet curing resin 52, the ultraviolet curing resin 52 is irradiated and cured with ultraviolet rays 58A by an ultraviolet irradiation device 58, and then the stamper is removed. Thus, the relief pattern of the stamper is transferred to the ultraviolet curing resin 52, so that the intermediate layer M1 provided with, for example, the land Ld and the groove Gv is formed on the information signal layer L0.

### Steps of Forming Information Signal Layer L1

The substrate 11 is then conveyed into the sputtering device 30 including the target 38 for forming the dielectric layer 23. As illustrated in FIGS. 5, 6A, and 6B, the substrate 11 is disposed on the placement surface 43S of the disk base 43, and the inner periphery and the outer periphery of a film-forming surface S1 of the intermediate layer M1 are covered with the inner mask 41 and the outer mask 42, respectively. The vacuum chamber 31 is then evacuated to a predetermined pressure. Thereafter, the target 38 is sputtered while process gas such as Ar gas or O₂ gas is introduced into the vacuum chamber 31, so that the dielectric layer 23 is formed on the film-forming surface S1 of the intermediate layer M1. At this point, the outer periphery of the film-forming surface S1 of the intermediate layer M1 is covered with the outer mask 42 such that the outer mask 42 does not come into contact with the film-forming surface S1 of the intermediate layer M1; meanwhile, the dielectric layer 23 is formed by sputtering.

The substrate 11 is then conveyed into the sputtering device 30 including the target 38 for forming the recording layer 21. The recording layer 21 is formed on the film-forming surface S0 of the substrate 11 through the same steps as the steps of forming the dielectric layer 23. At this point, the outer periphery of the film-forming surface S1 of the intermediate layer M1 is covered with the outer mask 42 such that the outer mask 42 does not come into contact with the film-forming surface S1 of the intermediate layer M1; meanwhile, the recording layer 21 is formed by sputtering.

The substrate 11 is then conveyed into the sputtering device 30 including the target 38 for forming the dielectric layer 22. The dielectric layer 22 is formed on the film-forming surface S0 of the substrate 11 through the same steps as the steps of forming the dielectric layer 23. At this point, the outer periphery of the film-forming surface S1 of the intermediate layer M1 is covered with the outer mask 42 such that the outer mask 42 does not come into contact with the film-forming surface S1 of the intermediate layer M1; meanwhile, the dielectric layer 22 is formed by sputtering.

### Steps of Forming Intermediate Layers M2 to Mn and Steps of Forming Information Signal Layers L2 to Ln

Subsequently, as in the steps of forming the intermediate layer M1 and the steps of forming the information signal layer L1, an intermediate layer M2, an information signal layer L2, . . . the intermediate layer Mn, and the information signal layer Ln are stacked in this order on the information signal layer L1.

### Step of Forming Light Transmitting Layer

Subsequently, a photosensitive resin such as an ultraviolet curing resin (UV resin) is spin-coated on the information signal layer Ln by, for example, a spin coating method, and then light such as ultraviolet rays is emitted to cure the photosensitive resin. Thus, the light transmitting layer 12 is formed on the information signal layer Ln.

Through the steps, a desired multilayer optical recording medium 10 is obtained.

### [1.5 Operation and Effect]

As described above, the sputtering device 30 according to the first embodiment includes the outer mask 42. The outer mask 42 is configured to be capable of covering the outer periphery of the film-forming surface Sn without coming into contact with the film-forming surface Sn of the intermediate layer Mn. Thus, when the information signal layer Ln, more specifically, the dielectric layer 22, the recording layer 21, and the dielectric layer 23 are formed on the film-forming surface Sn of the intermediate layer Mn by sputtering, the occurrence of scratches on the film-forming surface Sn of the intermediate layer Mn by the outer mask 42 can be suppressed even if the substrate 11 thermally expands in the in-plane direction. This can suppress the curling of the outer periphery of the intermediate layer Mn by a scratch of the outer mask 42. Thus, the occurrence of defects caused by the curling can be suppressed in the film-forming area R.

### 2 Second Embodiment

### [2.1 Overview]

In the first embodiment, an example of a sputtering device capable of suppressing the occurrence of defects caused by an outer mask was described. In the second embodiment, an example of a sputtering device capable of suppressing the occurrence of defects caused by an inner mask will be described.

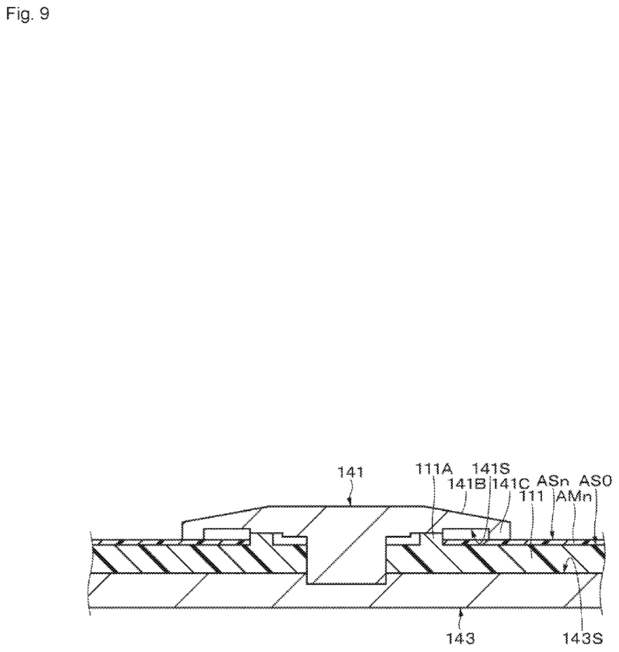

FIG. 9 is a cross-sectional view illustrating the configuration of an inner mask 141 provided for a conventional sputtering device. The inner mask 141 includes a protruding portion 141B that extends toward an outer mask 142 (see FIG. 1A) and protrudes in parallel with a placement surface 143S. The protruding portion 141B has a facing surface 141S that faces the placement surface 143S. The facing surface 141S has a convex portion 141C that protrudes toward the placement surface 143S. The substrate 111 has a convex portion 111A on the inner periphery of a film-forming surface ASn. The inner mask 141 presses, on the convex portion 141C, the inner periphery of the film-forming surface ASn of an intermediate layer AMn and presses, on a portion inside the convex portion 141C, the convex portion 111A of a substrate 111.

According to the findings of the present inventors, the provision of the inner mask 141 configured thus causes a defect in a recording region as follows. The convex portion 141C on the inner mask 141 comes into contact with the film-forming surface ASn of the intermediate layer AMn, causing a dent on the inner periphery of the film-forming surface ASn. In the steps of forming the intermediate layer AMn, when ultraviolet curing resin is spread from the inner periphery to the outer periphery of the substrate 111 by a spin coating method, bubbles are formed in the ultraviolet curing resin by the dent. The formed bubbles flow into the recording region according to the spread and cause a defect.

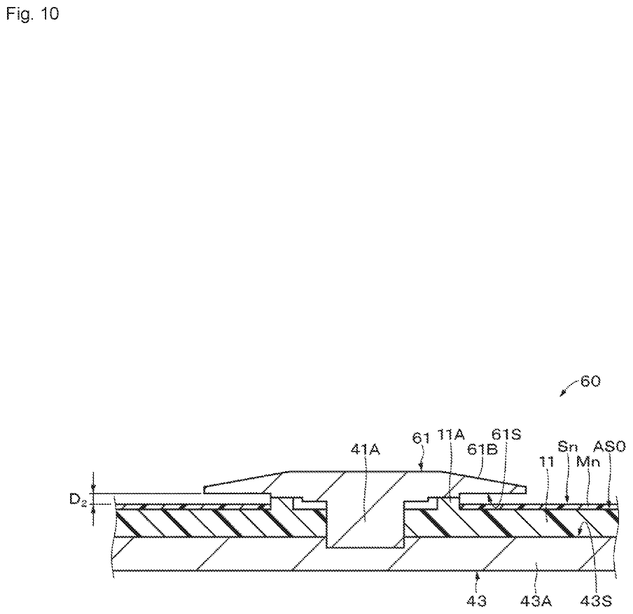

For this reason, the inventors eagerly examined the suppression of the defect. Consequently, as illustrated in FIG. 10, the inventors found a sputtering device 60 including an inner mask 61 configured to press a convex portion 11A without coming into contact with a film-forming surface Sn of an intermediate layer Mn in a region outside the convex portion 11A provided on the inner periphery of a film-forming surface AS0 of a substrate 11.

### [2.2 Configuration of Sputtering Device]

Referring to FIG. 10, an example of the configuration of the sputtering device 60 according to the second embodiment of the present disclosure will be described below. The sputtering device 60 according to the second embodiment is different from the sputtering device 30 according to the first embodiment in that the inner mask 61 is provided instead of the inner mask 41. In the second embodiment, the same parts as those in the first embodiment will be denoted by the same reference numerals, and descriptions thereof will be omitted.

The inner mask 61 is configured to be capable of covering the inner periphery of the film-forming surface Sn of the intermediate layer Mn and pressing the convex portion 11A without coming into contact with the film-forming surface Sn of the intermediate layer Mn in a region outside the convex portion 11A provided on the inner periphery of a film-forming surface S0 of the substrate 11. The inner mask 61 includes a base portion 41A and a protruding portion 61B.

The protruding portion 61B evenly protrudes from the inner periphery of the base portion 41A toward the inner mask 41. The protruding portion 61B has a facing surface 61S that faces a placement surface 43S, that is, the film-forming surface Sn of the intermediate layer Mn. The facing surface 61S is separated from the film-forming surface Sn of the intermediate layer Mn, outside the convex portion 11A on the outer periphery of the substrate 11. The facing surface 61S is in contact with the top of the convex portion 11A. The facing surface 61S may have a portion in contact with the top of the convex portion 11A such that the portion is a flat surface parallel to the placement surface 43S.

The facing surface 61S may have one or two or more steps. The steps may be configured such that the facing surface 61S is separated from the placement surface 43S from the inner mask 41 toward an outer mask 42. A portion between the steps may be brought into contact with the top of the convex portion. The portion between the steps may be a flat surface parallel to the placement surface 43S.

The inner mask 61 is configured to be capable of setting a distance between a facing surface D₂61S of the protruding portion 61B and the film-forming surface Sn of the intermediate layer Mn (hereinafter will be referred to as “flying height D₂ of the inner mask 61” as appropriate) preferably in a range of 50 μm to 400 μm and more preferably in a range of 150 μm to 400 μm outside the convex portion 11A on the outer periphery of the substrate 11.

### [2.3 Method for Manufacturing Multilayer Optical Recording Medium]

In a method for manufacturing the multilayer optical recording medium according to the second embodiment, the sputtering device having the foregoing configuration is used. The method for manufacturing the multilayer optical recording medium according to the second embodiment of the present disclosure is identical to the method for manufacturing the multilayer optical recording medium according to the first embodiment except for the steps of forming the information signal layer L0 and the steps of the information signal layers L1 to Ln.

In the steps of forming the information signal layer L0, the inner periphery of the film-forming surface S0 of the substrate 11 is covered with the inner mask 61, and the convex portion 11A is pressed by the inner mask 61 without coming into contact with the film-forming surface S0 of the substrate 11 in a region outside the convex portion 11A provided on the inner periphery of the substrate 11. Moreover, the outer periphery of the film-forming surface S0 of the substrate 11 is covered with the outer mask 42 such that the outer mask 42 does not come into contact with the film-forming surface S0 of the substrate 11. The inner mask 61 and the outer mask 42 are kept in this state; meanwhile, a dielectric layer 23, a recording layer 21, and a dielectric layer 22 are formed on the film-forming surface S0 of the substrate 11.

In the steps of forming information signal layers L1 to Ln, the inner peripheries of film-forming surfaces S1 to Sn of intermediate layers M1 to Mn are covered with the inner mask 61, and the convex portion 11A is pressed by the inner mask 61 without coming into contact with the film-forming surfaces S1 to Sn of the intermediate layers M1 to Mn in a region outside the convex portion 11A provided on the inner periphery of the substrate 11. Moreover, the outer peripheries of the film-forming surface S1 of the intermediate layers M1 to Mn are covered with the outer mask 42 such that the outer mask 42 does not come into contact with the film-forming surfaces S1 to Sn of the intermediate layers M1 to Mn. The inner mask 61 and the outer mask 42 are kept in this state; meanwhile, dielectric layers 23, recording layers 21, and dielectric layers 22 are formed on the film-forming surfaces S1 to Sn of the intermediate layers M1 to Mn.

### [2.4 Operation and Effect]

As described above, the sputtering device 60 according to the second embodiment includes the inner mask 61. The inner mask 61 is configured to be capable of pressing the convex portion 11A without coming into contact with the film-forming surface S0 of the substrate 11 in a region outside the convex portion 11A provided on the inner periphery of the substrate 11. Thus, when the dielectric layer 22, the recording layer 21, and the dielectric layer 23 are formed on the film-forming surface S0 of the substrate 11 by sputtering, the occurrence of a dent on the inner periphery of the film-forming surface S0 of the substrate 11 can be suppressed. Hence, in the steps of forming the intermediate layers M1 to Mn, when ultraviolet curing resin is spread from the inner periphery to the outer periphery of the substrate 11 by a spin coating method, the occurrence of a defect caused by a dent can be suppressed in a film-forming area R.

The sputtering device 60 according to the second embodiment includes the inner mask 61. The inner mask 61 is configured to be capable of pressing the convex portion 11A without coming into contact with the film-forming surfaces S1 to Sn of the intermediate layers M1 to Mn in a region outside the convex portion 11A provided on the inner periphery of the substrate 11. Thus, when the dielectric layers 22, the recording layers 21, and the dielectric layers 23 are formed on the film-forming surfaces S1 to Sn of the intermediate layers M1 to Mn by sputtering, the occurrence of a dent on the inner peripheries of the film-forming surfaces S1 to Sn of the intermediate layers M1 to Mn can be suppressed. Hence, in the steps of forming the intermediate layers M2 to Mn, when ultraviolet curing resin is spread from the inner periphery to the outer periphery of the substrate 11 by the spin coating method, the occurrence of a defect caused by a dent can be suppressed in the film-forming area R.

### 3 Modification Examples

### Modification Example 1

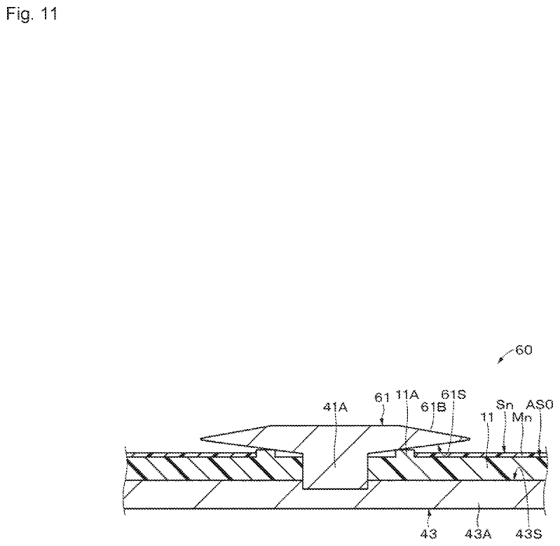

The second embodiment described an example in which the facing surface 61S of the inner mask 61 has a portion in contact with the top of the convex portion 11A such that the portion is a flat surface. The shape of the facing surface 61S is not limited thereto. For example, as illustrated in FIG. 11, in the facing surface 61S, a portion in contact with the top of the convex portion 11A may be tapered. In the example of FIG. 11, the facing surface 61S is entirely tapered. A part of the facing surface 61S may be tapered. The taper may be configured such that the facing surface 61S is separated from the placement surface 43S from the inner mask 41 toward the outer mask 42.

In the steps of forming the intermediate layers M1 to Mn, when ultraviolet curing resin is spread from the inner periphery to the outer periphery of the substrate 11 by the spin coating method, the center cap 51 is fit to the center hole of the substrate 11 (see FIGS. 7A and 7D). At this point, at least a part of the top of the convex portion 11A is exposed without being covered with the cap. Hence, in the presence of a dent at the top of the convex portion 11A, when ultraviolet curing resin is spread from the inner periphery to the outer periphery of the substrate 11 by the spin coating method, the dent may cause bubbles in the ultraviolet curing resin. The formed bubbles may flow into the recording region according to the spread and cause a defect.

On the inner mask 61 in modification example 1, the facing surface 61S has a portion tapered in contact with the top of the convex portion 11A, thereby reducing a contact area between the top of the convex portion 11A and the inner mask 61. Thus, when the dielectric layer 22, the recording layer 21, and the dielectric layer 23 are formed on the film-forming surface S0 of the substrate 11 and the film-forming surfaces S1 to Sn of the intermediate layers M1 to Mn by sputtering, the occurrence of a dent at the top of the convex portion 11A can be further suppressed. Thus, the occurrence of defects caused by a dent on the convex portion 11A can be further suppressed in the film-forming area R.

In the foregoing example, the facing surface 61S has a portion tapered in contact with the top of the convex portion 11A. The facing surface 61S may have a stepped portion in contact with the top of the convex portion 11A. Steps may be configured such that the facing surface 61S is separated from the placement surface 43S from the inner mask 41 toward the outer mask 42.

### Modification Example 2

The first and second embodiments described examples of the multilayer optical recording medium formed by the sputtering device, the multilayer optical recording medium having a configuration in which a plurality of layers include the information signal layer and the light transmitting layer stacked in this order on the substrate, wherein the information signal is recorded or reproduced by emitting a laser beam from the light transmitting layer to the information signal layer. However, the multilayer optical recording medium that can be formed by the sputtering device is not limited to this example.

For example, the sputtering device may be capable of forming a multilayer optical recording medium (e.g., a CD (Compact Disc)) having a configuration in which a plurality of layers include the information signal layer and the protective layer stacked in this order on the substrate, wherein the information signal is recorded or reproduced by emitting a laser beam from the substrate to the information signal layers.

The sputtering device may be capable of forming a multilayer optical recording medium (e.g., a DVD (Digital Versatile Disc)) having a configuration in which information signal layers are provided between two substrates, wherein the information signal is recorded or reproduced by emitting a laser beam from one of the substrates to the information signal layers.

The sputtering device may be capable of forming a multilayer optical recording medium (e.g., an AD (Archival Disc)) having a configuration in which a first disc and a second disc are bonded to each other, wherein the information signal of the first disc is recorded or reproduced by emitting a laser beam from a surface of the first disc and the information signal of the second disc is recorded or reproduced by emitting a laser beam from a surface of the second disc. The first disc and the second disc may have the same layer configuration as the multilayer optical recording medium 10 according to the first embodiment.

### Modification Example 3

The first and second embodiments described examples in which the multilayer optical recording medium formed by the sputtering device is a write-once multilayer optical recording medium. The sputtering device may be capable of forming the films of a rewritable multilayer optical recording medium and a playback-only multilayer optical recording medium.

### Other Modification Examples

While embodiments and modification examples of the present disclosure have been described above in detail, the present disclosure is not limited to the above embodiments and modification examples, and various modifications based on the technical idea of the present disclosure can be made. For example, the configurations, methods, processes, shapes, materials, and numerical values in the above embodiments and modification examples are merely exemplary, and different configurations, methods, processes, shapes, materials, and numerical values may be used as necessary. The configurations, methods, processes, shapes, materials, and numerical values or the like of the above embodiments and modification examples can be combined with each other without departing from the gist of the present disclosure. In the numerical ranges described in stages in the above embodiments and modification examples, the upper limit value or the lower limit value of the numerical range of a certain stage may be replaced with the upper limit value or the lower limit value in the numerical range of another stage. Unless otherwise specified, the materials exemplified in the above embodiments and modification examples may be used alone or two or more thereof may be used in combination.

In addition, the present disclosure may have the following constitutions.

(1)

A sputtering device for a multilayer optical recording medium, the sputtering device including an outer mask, wherein the outer mask is configured to be capable of covering the outer periphery of the film-forming surface of an intermediate layer without coming into contact with the film-forming surface.

(2)

The sputtering device for the multilayer optical recording medium according to (1), the sputtering device further including an inner mask, wherein the inner mask is configured to be capable of covering the inner periphery of the film-forming surface and pressing a convex portion without coming into contact with the film-forming surface in a region outside the convex portion provided on the inner periphery of a substrate.

(3)

The sputtering device for the multilayer optical recording medium according to (2), wherein the inner mask has a taper on a portion in contact with the convex portion.

(4)

The sputtering device for the multilayer optical recording medium according to any one of (1) to (3), wherein the outer mask has a facing surface that faces the film-forming surface, and
the outer mask is configured to be capable of setting a distance between the facing surface and the film-forming surface in a range of 50 μm to 400 μm.
   (5)

The sputtering device for the multilayer optical recording medium according to (4), wherein the outer mask is configured to be capable of setting a distance between the facing surface and the film-forming surface in a range of 150 μm to 400 μm.

(6)

A sputtering device for a multilayer optical recording medium, the sputtering device including an inner mask,
wherein the inner mask is configured to be capable of covering the inner periphery of a substrate or the film-forming surface of an intermediate layer and pressing a convex portion without coming into contact with the film-forming surface in a region outside the convex portion provided on the inner periphery of the substrate.
   (7)

A method for manufacturing a multilayer optical recording medium, the method including forming an inorganic layer on the film-forming surface of an intermediate layer by sputtering while covering the outer periphery of the film-forming surface with an outer mask such that the outer mask does not come into contact with the film-forming surface.

(8)

The method for manufacturing a multilayer optical recording medium according to (7), wherein when the inorganic layer is formed, the inner periphery of the film-forming surface is covered with an inner mask and a convex portion is pressed by the inner mask without coming into contact with the film-forming surface in a region outside the convex portion provided on the inner periphery of a substrate.

### 4 EXAMPLES

The present disclosure will be described below in detail with reference to examples. The present disclosure is not limited to these examples.

In the following description, three information signal layers provided for a three-layer optical recording medium will be referred to as “L0 layer,” “L1 layer,” and “L2 layer” in order from the substrate toward the laser beam irradiation surface. Moreover, four information signal layers provided for a four-layer optical recording medium will be referred to as “L0 layer,” “L1 layer,” “L2 layer,” and “L3 layer” in order from the substrate toward the laser beam irradiation surface.

### Examples 1 to 3

### (Step of Molding Substrate)

First, a polycarbonate substrate was molded by injection molding. One main surface of the polycarbonate substrate was an uneven surface composed of lands and grooves.

### (Step of Forming L0 Layer)

Subsequently, by using the sputtering device illustrated in FIGS. 5, 6A, and 6B, a second dielectric layer, a recording layer, and a first dielectric layer were sequentially stacked on the uneven surface of the polycarbonate substrate by a sputtering method, so that the L0 layer was formed.

### (Step of Forming Intermediate Layer)

Thereafter, the intermediate layer was formed on the L0 layer according to the steps described in the first embodiment.

### (Steps of Forming L1 Layer)

Subsequently, by using the sputtering device illustrated in FIGS. 5, 6A, and 6B, a second dielectric layer, a recording layer, and a first dielectric layer were sequentially stacked on the uneven surface of the intermediate layer by the sputtering method, so that the L1 layer was formed. The flying height D₁ (see FIG. 6B) of the outer mask of the sputtering device was set at 50 nm (example 1), 150 nm (example 2), and 250 nm (example 3) as shown in Table 1. The inner mask illustrated in FIG. 9 was used.

### (Steps of Forming Intermediate Layers and Steps of Forming L2 Layer and L3 Layer)

Subsequently, as in the steps of forming the intermediate layer and the steps of forming the L1 layer, the intermediate layer, the L2 layer, the intermediate layer, and the L3 layer were stacked in this order on the L1 layer.

(Step of forming light transmitting layer)

Thereafter, ultraviolet curing resin was uniformly applied onto the L3 layer by a spin coating method and was irradiated and cured with ultraviolet rays, so that the light transmitting layer was formed. Accordingly, a four-layer optical recording medium was obtained.

### Comparative Example 1

In the steps of forming the L1 layer, the L2 layer, and the L3 layer, a four-layer optical recording medium was obtained as in example 1 except for the use of the outer mask illustrated in FIGS. 1A and 1B.

### [Evaluation of Yield]

The outer periphery of the optical recording medium was inspected by using IQPC Blu of Dr. Schwab Inspection Technology GmbH, a pass/fail decision was made such that an optical recording medium with a defect of 500 μm or larger is set as a reject, and then the yield was calculated. Table 1 shows the number of inspection discs used for calculating the yield.

### [Evaluation of Defect Occurrence Rate Caused by Contact of Mask]

In the evaluation of the yield, the outer periphery of an optical recording medium judged as being defective was confirmed through an optical microscope, whether the defect was caused by the curling of the intermediate layer was confirmed, and then optical recording media having defects caused by curling were counted. The occurrence rate of optical recording media with defects caused by curling was calculated, and the result of calculation was used as the occurrence rate of defects caused by the contact of the mask. The evaluation results of the occurrence rates of defects are shown in Table 1.

TABLE 1

| | | Number of | | Occurrence |
|---|---|---|---|---|
| | | media | | rate of defect |
| | | having been | | caused by |
| | Flying height | checked for | | contact of |
| | D₁ [μm] | defects | Yield [%] | mask [%] |
| Comparative | 0 | 1000 | 65 | 30.2 |
| example 1 | | | | |
| Example 1 | 50 | 1800 | 85 | 12.8 |
| Example 2 | 150 | 1000 | 98 | 0 |
| Example 3 | 250 | 1000 | 97 | 0 |

The following can be seen from Table 1.

The occurrence of defects can be suppressed by forming the L1 layer, the L2 layer, and the L3 layer on the film-forming surface of the intermediate layer while covering the outer periphery of the film-forming surface of the intermediate layer with the outer mask such that the outer mask does not come into contact with the film-forming surface of the intermediate layer.

In view of the suppression of the defect occurrence rate, the flying height D₁ of the outer mask is preferably 150 μm or more.

### Examples 4 to 6

An optical recording medium was obtained as in example 1 except for the setting of the flying height D₁ of the outer mask at 200 μm (example 4), 300 μm (example 5), and 400 μm (example 6). A mask edge thickness T of the outer mask was set at 0.55 mm (see FIG. 1).

### [Evaluation of Reflectance]

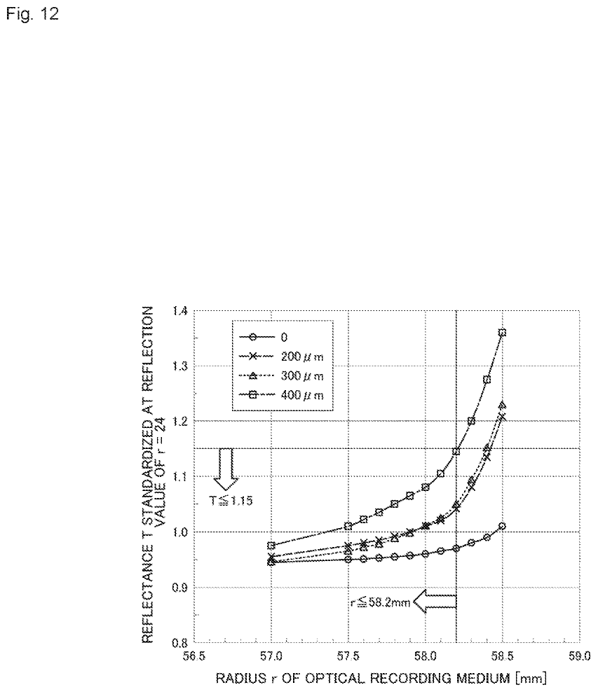

The reflectance of the optical recording medium was measured in a range of 57.0 mm to 58.0 mm in radius. The results are shown in FIG. 12. It is understood from FIG. 12 that the reflectance can be set at 1.15 or less with a radius of 58.2 mm or less. In other words, it is found that a change of a reflectance on the outer periphery of the optical recording medium can be suppressed.

### Example 7

In the steps of forming three information signal layers: the L0 layer, the L1 layer, and the L2 layer, a three-layer optical recording medium was obtained as in example 1 except for the use of the inner mask illustrated in FIG. 10. The flying height D₂ (see FIG. 10) of the inner mask was set at 230 μm.

### Comparative Example 2

In the steps of forming the L0 layer, the L1 layer, and the L2 layer, a three-layer optical recording medium was obtained as in example 7 except for the use of the inner mask illustrated in FIG. 9.

### [Evaluation of Dent Occurrence Rate]

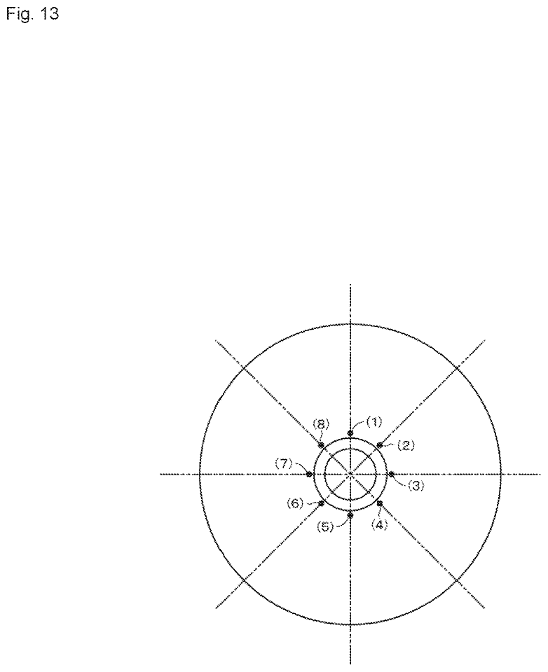

In the steps of manufacturing the optical recording medium, the inner periphery of the film-forming surface (a portion facing the edge of the inner mask) of the substrate was observed through an optical microscope after the formation of the L0 layer. Likewise, after the formation of the L1 layer and the L2 layer, the inner periphery of the film-forming surface (a portion facing the edge of the inner mask) of the intermediate layer was observed through an optical microscope. As shown in FIG. 13, the inner peripheries were observed at eight positions (1) to (8) in total at 45-degree intervals in the circumferential direction. When a dent of 100 μm or more was confirmed in the field of view in the observation of the inner peripheries, the presence of a dent was determined. The occurrence rate of dents was calculated by the following formula. The evaluation results of the occurrence rates of dents are shown in Table 2.

Dent occurrence rate [%]=((the number of positions where dents are confirmed among eight positions (1) to (8))/8)×100

TABLE 2

| | Observed | | | | | | | | | Dent |
|---|---|---|---|---|---|---|---|---|---|---|
| | information | | | | | | | | | occurrence |
| | signal | Measurement point | | | | | | | | rate |
| | layer | (1) | (2) | (3) | (4) | (5) | (6) | (7) | (8) | [%] |
| Example 7 | L0 layer | present | absent | absent | present | absent | absent | absent | present | 37.5 |
| | L1 layer | absent | absent | absent | absent | absent | absent | absent | absent | 0 |
| | L2 layer | absent | absent | absent | absent | absent | absent | absent | absent | 0 |
| Comparative | L0 layer | present | present | present | present | present | present | present | present | 100.0 |
| example2 | L1 layer | present | present | present | absent | absent | absent | absent | absent | 37.5 |
| | L2 layer | present | present | absent | present | present | absent | present | present | 75.0 |

In Table 2, “present” indicates a determination result of “dent”, whereas “absent” indicates a determination result of “no dent.”

The following can be seen from Table 2.

The occurrence of dents can be suppressed by forming the L1 layer, the L2 layer, and the L3 layer on the film-forming surface while covering the inner periphery of the film-forming surface with the inner mask such that the inner mask does not come into contact with the film-forming surface in a region outside the convex portion provided on the inner periphery of the substrate.

It is assumed that even a floating mask causes a dent because the substrate is curled to form a dent as a temperature increases on the substrate during the formation of the recording layer. It is assumed that the L0 layer includes the recording layer having a larger thickness than those of the L1 layer and the L2 layer and thus the substrate has a higher temperature and causes a high occurrence rate.

### REFERENCE SIGNS LIST

10 Optical recording medium
11 Substrate
11A Convex portion
12 Light transmitting layer
21 Recording layer
22 Dielectric layer
30 Sputtering device
31 Vacuum chamber
32 Vacuum control unit
33 Plasma-discharge DC high-voltage power supply
34 Power supply line
35 Sputtering cathode part
36 Palette
37 Sputtering gas supply unit
38 Target
39 Backing plate
40 Magnet system
41, 61 Inner mask
41A, 42A Base portion
41B, 42B, 61B Protruding portion
42 Outer mask
42C Convex portion
42S, 61S Facing surface
43 Disc base
43A Plate
43B Wall portion
43S Placement surface
L0 to Ln Information signal layer
M1 to Mn Intermediate layer
S0 to Sn film-forming surface
Ld Land
Gv Groove
C Light irradiation surface

1. A sputtering device for a multilayer optical recording medium, the sputtering device comprising an outer mask,
wherein the outer mask is configured to be capable of covering an outer periphery of a film-forming surface of an intermediate layer without coming into contact with the film-forming surface.

2. The sputtering device for the multilayer optical recording medium according to claim 1, the sputtering device further comprising an inner mask,
wherein the inner mask is configured to be capable of covering an inner periphery of the film-forming surface and pressing a convex portion without coming into contact with the film-forming surface in a region outside the convex portion provided on an inner periphery of a substrate.

3. The sputtering device for the multilayer optical recording medium according to claim 2, wherein the inner mask has a taper on a portion in contact with the convex portion.

4. The sputtering device for the multilayer optical recording medium according to claim 1, wherein the outer mask has a facing surface that faces the film-forming surface, and
the outer mask is configured to be capable of setting a distance between the facing surface and the film-forming surface in a range of 50 μm to 400 μm.

5. The sputtering device for the multilayer optical recording medium according to claim 4, wherein the outer mask is configured to be capable of setting a distance between the facing surface and the film-forming surface in a range of 150 μm to 400 μm.

6. A sputtering device for a multilayer optical recording medium, the sputtering device comprising an inner mask,
wherein the inner mask is configured to be capable of covering an inner periphery of a substrate or a film-forming surface of an intermediate layer and pressing a convex portion without coming into contact with the film-forming surface in a region outside the convex portion provided on the inner periphery of the substrate.

7. A method for manufacturing a multilayer optical recording medium, the method comprising forming an inorganic layer on a film-forming surface of an intermediate layer by sputtering while covering an outer periphery of the film-forming surface with an outer mask such that the outer mask does not come into contact with the film-forming surface.

8. The method for manufacturing a multilayer optical recording medium according to claim 7, wherein when the inorganic layer is formed, an inner periphery of the film-forming surface is covered with an inner mask and a convex portion is pressed by the inner mask without coming into contact with the film-forming surface in a region outside the convex portion provided on an inner periphery of a substrate.
